(19) United States
(12) Patent Application Publication
(10) Pub. No.: US 2009/0191468 A1
(43) Pub. Date: Jul. 30, 2009

(54) Contact Level Mask Layouts By Introducing Anisotropic Sub-Resolution Assist Features

(75) Inventors: Michael M. Crouse, Albany, NY (US); Derren N. Dunn, Sandy Hook, CT (US); Henning Haffner, Pawling, NY (US); Michael E. Scaman, Goshen, NY (US)

Correspondence Address: HOFFMAN WARNICK LLC, 75 STATE ST, 14TH FL, ALBANY, NY, 12207, US

(73) Assignees: INTERNATIONAL BUSINESS MACHINES CORPORATION, Armonk, NY (US); INFINEON TECHNOLOGIES NORTH AMERICA CORPORATION, Milpitas, CA (US)

(21) Appl. No.: 12/021,527

(22) Filed: Jan. 29, 2008

(51) Int. Cl. G03F 1/00

(52) U.S. Cl. 430/5

(57) ABSTRACT

This disclosure includes a SRAF layout that minimizes the number of SRAFs required to reliably print contact shapes. A method is provided that reduces the number of necessary SRAF features on a mask, placing at least two elongated SRAF shapes on the mask such that the elongated SRAF shapes extend past at least one edge of a mask shape in at least one direction.

### BACKGROUND

1. Technical Field

This disclosure relates generally to computational lithography and optical proximity correction (OPC) in connection with integrated circuit (IC) chip fabrication, and more particularly, to methods of placing sub-resolution assist features (SRAF) on a mask.

2. Background Art

To ensure that specific features of very large scale integrated circuits can be printed, mask shapes most often require manipulation to ensure manufacturability. Often, this means that sub-resolution assist features (SRAF) shapes are placed on a mask to artificially create an optically nested environment for mask features, which subsequently increases the features' individual process windows.

Introducing SRAF into photolithography masks in order to improve manufacturability has a long and rich history. SRAF have successfully been used to extend technology nodes with nominal lithography processes to higher and higher transistor densities. Placing SRAF on a mask has become a complex undertaking that requires significant computational resources to accomplish for modern technology nodes. As critical dimensions for technology nodes have shrunk, the difficulty in effectively placing SRAF features has increased geometrically. In dense layouts, it is typically found that mask features will appear optically nested along one principle direction, but isolated along an orthogonal direction. If SRAF are placed using typical n-SRAF per edge strategies, it is possible to actually degrade process window measures for assisted features. In other words, using the traditional placement of 1-SRAF per edge increases a mask error enhancement factor (MEEF).

Another difficulty in placing SRAF is that in many dense layouts, rules based SRAF placement leads to the superposition of SRAF that leave oddly shaped residual SRAF and small features that need to be scrubbed from layouts. This scrubbing process tends to lead to complex placement and clean-up algorithms that are prone to errors.

Another issue that typically arises is whether a computed mask layout with a given SRAF strategy can actually be written by current mask writers. One of the key elements that tends to push the limits of mask writing technology is the ability to write SRAF features of dimensions that are large enough to increase process window, but small enough to avoid SRAF printing. Assuming that these features can be written by mask writers, a second complication is trying to place these features in dense environments on the mask layout. With many conventional SRAF strategies, the required density of SRAF is so high, that inevitably SRAF are placed at distance from adjacent features that is not writeable by existing tools.

### SUMMARY

Methods of improving SRAF layouts are disclosed. In one embodiment, the method includes reducing the number of necessary SRAF features on a mask to improve manufacturability for contact levels.

A first aspect of the disclosure provides a method to reduce the number of necessary SRAF features on a mask, the method comprising: providing a mask; the mask including a mask shape; and placing at least two elongated SRAF shapes on the mask such that each elongated SRAF shape extends past at least one edge of the mask shape in at least one direction.

A second aspect of the disclosure provides a mask with an improved SRAF layout, the mask comprising: a mask shape; at least two elongated SRAF shapes, such that each of the elongated SRAF shapes extend past at least one edge of the mask shape.

A third aspect of the disclosure provides a machine-readable medium having stored thereupon a set of instructions that, when executed by a machine, result in: providing a mask; the mask including a mask shape; and placing at least two elongated SRAF shapes on the mask such that each elongated SRAF shape extends past at least one edge of the mask shape in at least one direction.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a conventional SRAF placement for a contact layout.

FIG. 2 shows a focus exposure matrix simulated for conventional contact SRAF schemes.

FIG. 3 shows exposure latitude as a function of depth of focus (DOF) for the contact feature and SRAF layout shown in FIG. 1.

FIG. 4 shows a contact layout with an improved SRAF layout according to one embodiment of the present invention.

FIG. 5 shows a focus exposure matrix simulated for the contact feature and SRAF layout shown in FIG. 4.

FIG. 6 shows the exposure latitude as a function of depth of focus (DOF) for the contact feature and SRAF layout shown in FIG. 4.

FIG. 7 shows an alternative improved SRAF layout according to another embodiments of the present invention.

FIG. 8 shows a flow diagram of a design process used in semiconductor design, manufacture, and/or test.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

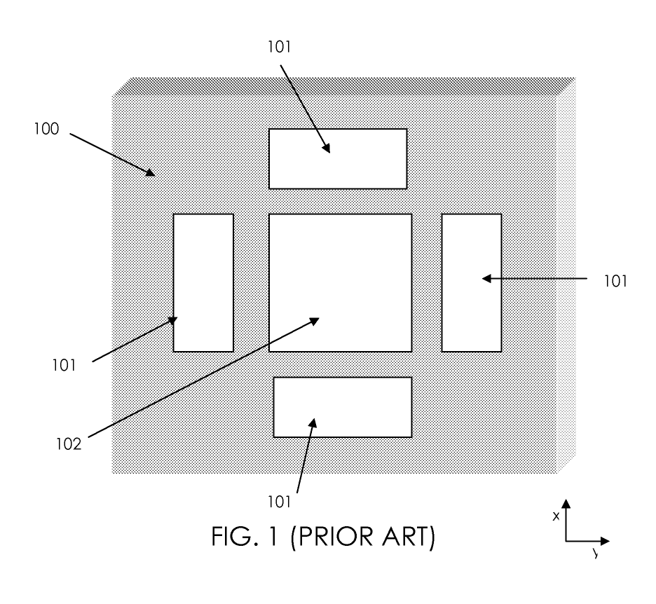

This disclosure provides improved layouts of SRAFs on a mask. Conventional layouts for SRAF tend to focus on the benefits, placement and sizing of SRAF. Conventionally, as shown in FIG. 1, four orientations of SRAFs are placed on a mask around a mask shape. FIG. 1 shows a mask 100 with a conventional layout containing a mask shape and corresponding SRAFs 101 placed to enhance, i.e., increase, the process window for this mask shape 102, a target for a contact in this case. In most cases, four SRAFs 101 are placed as shown in FIG. 1 to increase the nested character of this contact along the principle directions of this contact, which appear as the x- and y-direction in FIG. 1.

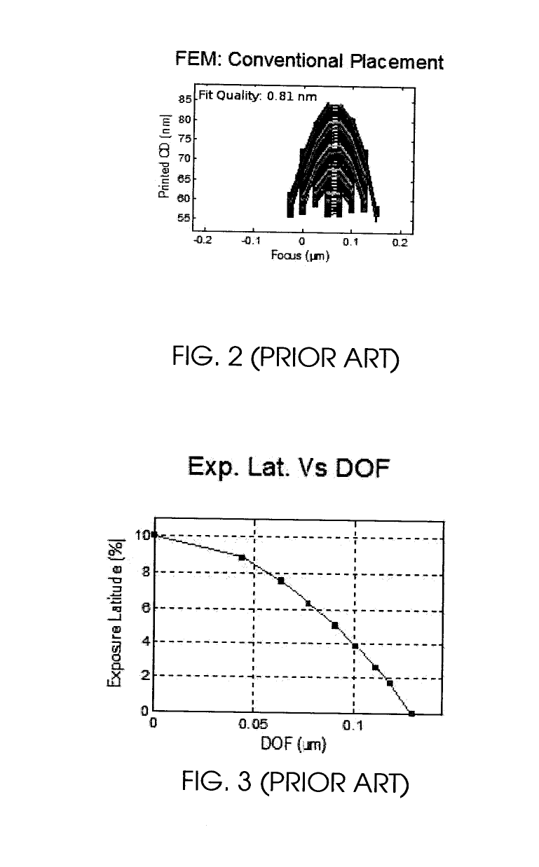

FIGS. 2 and 3 show testing for the layout shown in FIG. 1. FIG. 2 is a focus exposure matrix (FEM), which is a measure of process window. Specifically, FIG. 2 shows printed CD versus focus value for different dose values within a certain percentage range. Printed CD is the critical dimension of a resist feature after lithography. The flatter the curvature of a group of printed CD vs focus curves, the larger the process window. FIG. 3 plots exposure latitude against depth of focus. Exposure latitude means a percent variation around a fixed nominal dose that a lithography tool will be run. In order for a lithography process to be viable, allowances need to be made for drift in exposure or dose because exposure tools do not have absolute controls. As such, process windows are quoted for a deviation in percentage around the nominal dose, so that if the exposure tools drift, it can still be ensured that a given feature set will print. It is shown through the focus-exposure matrix (FEM) (shown in FIG. 2) and process window analysis (shown in FIG. 3) calculated for this contact arrangement, that the arrangement of SRAFs 101 in FIG. 1 have provided the necessary process window to print this contact 102.

This disclosure seeks to improve SRAF layouts to reduce potential mask error factor (MEEF) implications, mask rules check (MRC) violations and SRAF placement difficulties for dense layouts. MEEF implications present serious concerns to most lithographic processes because small errors in mask construction can lead to serious process window degradation. One of the problems with placing SRAF to increase process window is that the effective environment of a mask feature becomes more nested due to SRAF, which results in a general tendency of MEEF to increase. This increase in MEEF degrades the effectiveness of SRAF in boosting process window and may well offset their benefit. In this disclosure, the pattern density along one direction is reduced by removing SRAF shapes, thereby significantly decreasing the contribution of pattern density from this dimension to MEEF.

In addition to reducing two-dimensional MEEF, the improved SRAF placement suggested in this disclosure reduces the risk of encroaching MRC constraints during the mask making process. MRC constraints are put in place during layout design processes to ensure manufacturability. Very often, contacts are placed in close enough proximity that the introduction of SRAF creates mask spaces that are too small to be manufactured. This process becomes particularly acute for staggered contact layouts where a contact requires SRAF, but SRAF for adjacent contacts will be placed at distances that are too small to be cut by the mask writing process. Using the current disclosure, the probability of this situation occurring is significantly reduced because half of the SRAF shapes required to achieve process window specifications are removed.

Another equally important area that this disclosure will contribute to is the area of SRAF placement on masks with high feature density. Typically, in high feature density masks, a great deal of computational time and effort is spent to remove SRAF collisions and overlaps during placement on contact levels. This problem is particularly acute for layouts with staggered contacts and those where lines of contacts are placed. This disclosure reduces the computational complexity required to effectively place SRAF and may well lead to more process stability for a given contact level.

Another area where this disclosure will be particularly useful is for layouts that contain lines of contacts along a single direction. Typically, lines are contacts that are placed so that they are effectively nested along one direction, but they appear optically isolated along an orthogonal direction. These contacts are difficult to provide assist features for because the mask process is required to write a large number of small features along the dense direction. These small SRAF in the isolated areas are spaced closely due to the tight pitch along the nested direction and tend to lead to manufacturing problems and MRC violations. This disclosure addresses these problems by replacing this row of SRAF with a single long SRAF, thereby reducing the complexity of the mask process for these SRAF configurations.

As discussed above, this disclosure includes an improved layout of SRAFs, including sandwiching the mask shape between two or more anistropic, i.e., elongated SRAFs, instead of the conventional four orientations of SRAF. In this way, the design intent is conservatively preserved; leaving the target for OPC the same, but the OPC will tend to be wider in the direction of no SRAF, and tend to be more narrow in the direction of SRAFs.

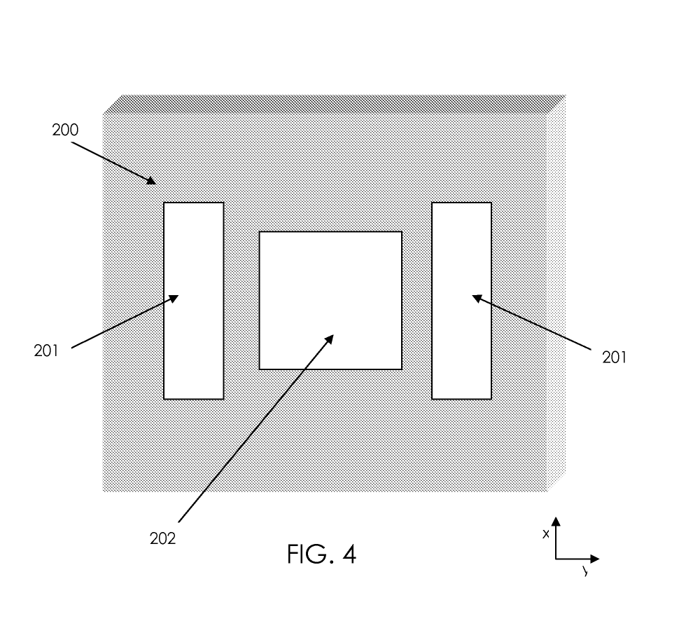

An improved layout of this disclosure is shown in FIG. 4. A mask 200 is provided, with a mask shape 202, for a contact in this case. Rather than placing four SRAF along each side of the contact, as in the prior art, this improved layout includes two elongated SRAFs 201 on the left and right side of the contact (as illustrated). As shown in FIG. 4, the elongated SRAF shapes 201 can be placed such that each elongated SRAF shape 201 is substantially parallel to a different edge of the mask shape 202. (Although FIG. 4 shows two SRAF shapes, more or less shapes may be used to achieve the goals of this disclosure.) The dimensions and distance of these SRAFs 201 are calculated based upon lithographic simulations and are chosen to improve, i.e., increase, process window while avoiding SRAF feature printing. For example, the ratio of the length of a longer side of the elongated SRAF (i.e., the length alongside the contact, or mask shape) to the mask shape edge length shape can be greater than or equal to approximately 1.2.

The improved layout shown in FIG. 4 illustrates that two SRAF shapes 201 can placed on different sides of the mask shape such that the two SRAF shapes 201 are substantially parallel to each other. In another layout, the two SRAF shapes can be placed on different sides of the mask shape such that the two SRAF shapes are substantially perpendicular to each other. In addition, the SRAF shapes 201 can extend past at least one edge of the mask shape 202. (FIG. 4 illustrates a layout where the SRAF shapes 201 extend past two edges of the mask shape 202).

This anisotropic layout of FIG. 4 has better MEEF and an equivalent or better process window than the conventional layout shown in FIG. 1. Also, the anisotropic layout allows larger SRAFs for improved, i.e., increased, process window and lower MEEF, which may be purposefully different in one orientation than another for DFM reasons.

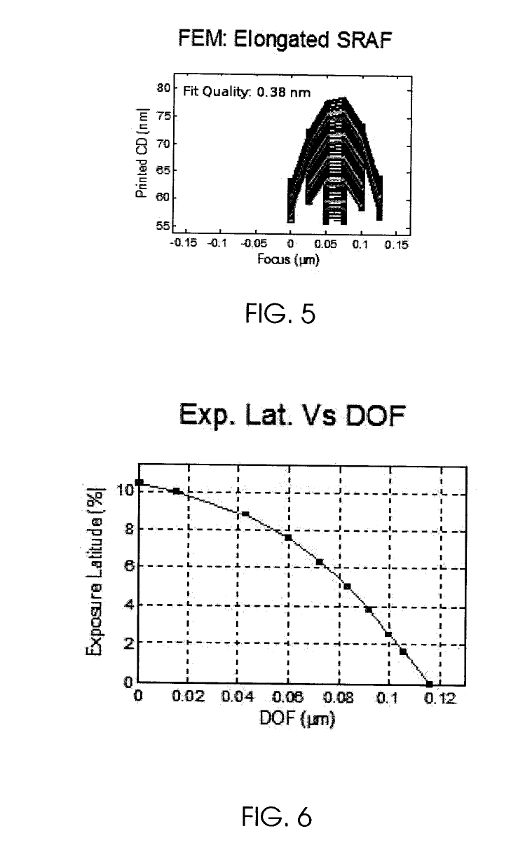

FIGS. 5 and 6 show the results of testing of the anisotropic layout illustrated in FIG. 4. FIG. 5 shows the FEM analysis of the layout in FIG. 4, and FIG. 6 shows the process window plot for the layout in FIG. 4. Comparing the FEM in FIG. 5 and the process window plot in FIG. 6 to those shown in FIGS. 2 and 3, respectfully, it is clear that by removing two SRAF on the top and bottom of the contact, and increasing the aspect ratio of those SRAF on the right and left hand side of the mask shape, an equivalent process window is achieved.

Various other layouts of SRAFs are possible to achieve the goal of this disclosure—to reduce the number of necessary SRAF features on a mask and still retain substantially the same or better characteristics. For example, the placement of two or more elongated SRAFs 201 can be determined by whether the contact is hitting a line of an underlying substrate. In other words, the placement of the elongated SRAFs could be based on whether the contact is sitting on or next to a line and hence the line and its intended (overlay) relationship with the contact becoming a guide to determining the orientation of the sandwiches SRAF. For example, the elongated SRAF shapes can be placed such that the SRAF shapes do not overlap the line of the underlying substrate.

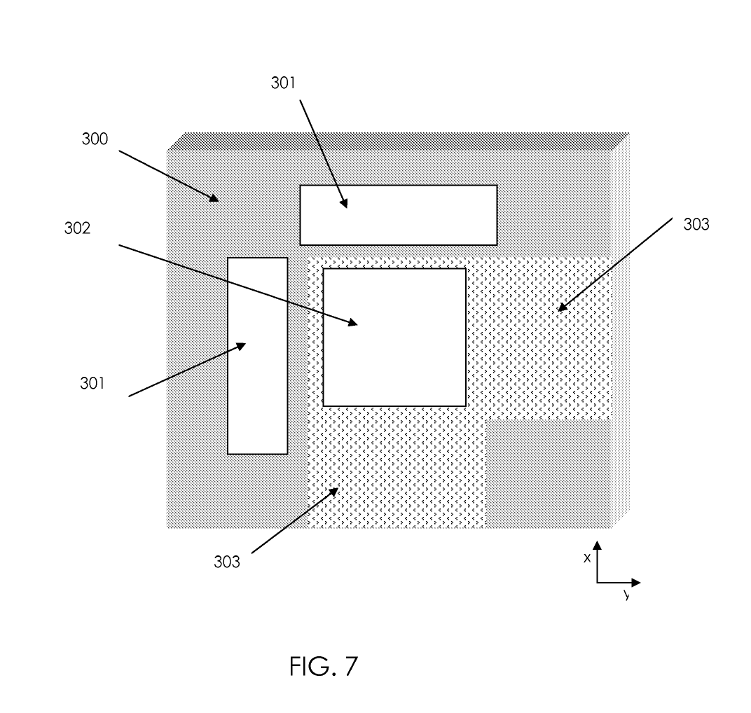

In another example, as shown in FIG. 7, an alternative layout of SRAFs is shown. In FIG. 7, a mask 300 is provided, with a mask shape 302, for a contact in this case. SRAFs 301 are placed on two perpendicular sides of the mask shape 302, i.e. contact, because the line 303 extends from the other sides of the mask shape.

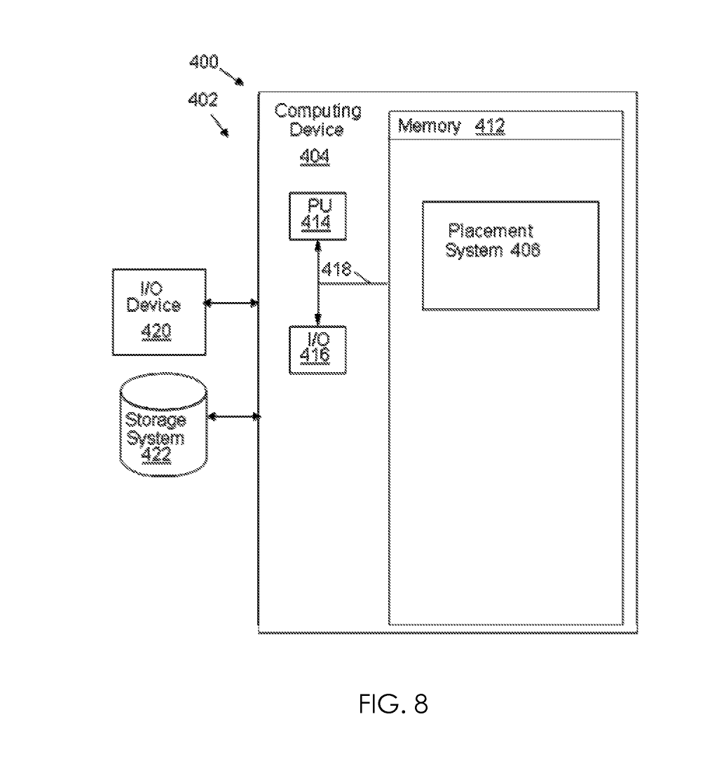

Turning to the drawings, FIG. 8 shows an illustrative environment 400 for optimizing placement of SRAF shapes on a mask. To this extent, environment 400 includes a computer infrastructure 402 that can perform the various process steps described herein for optimizing the placement of SRAF shapes on a mask. In particular, computer infrastructure 402 is shown including a computing device 404 that comprises a placement system 406, which enables computing device 404 to optimize the placement of SRAF shapes on a mask by performing the steps of the disclosure.

Computing device 404 is shown including a memory 412, a processor (PU) 414, an input/output (I/O) interface 416, and a bus 418. Further, computing device 404 is shown in communication with an external I/O device/resource 420 and a storage system 422. As is known in the art, in general, processor 414 executes computer program code, such as system 406, that is stored in memory 412 and/or storage system 422. While executing computer program code, processor 414 can read and/or write data, to/from memory 412, storage system 422, and/or I/O interface 416. Bus 418 provides a communications link between each of the components in computing device 404. I/O device 418 can comprise any device that enables a user to interact with computing device 404 or any device that enables computing device 404 to communicate with one or more other computing devices. Input/output devices (including but not limited to keyboards, displays, pointing devices, etc.) can be coupled to the system either directly or through intervening I/O controllers.

In any event, computing device 404 can comprise any general purpose computing article of manufacture capable of executing computer program code installed by a user (e.g., a personal computer, server, handheld device, etc.). However, it is understood that computing device 404 and system 406 are only representative of various possible equivalent computing devices that may perform the various process steps of the disclosure. To this extent, in other embodiments, computing device 404 can comprise any specific purpose computing article of manufacture comprising hardware and/or computer program code for performing specific functions, any computing article of manufacture that comprises a combination of specific purpose and general purpose hardware/software, or the like. In each case, the program code and hardware can be created using standard programming and engineering techniques, respectively.

Similarly, computer infrastructure 402 is only illustrative of various types of computer infrastructures for implementing the disclosure. For example, in one embodiment, computer infrastructure 402 comprises two or more computing devices (e.g., a server cluster) that communicate over any type of wired and/or wireless communications link, such as a network, a shared memory, or the like, to perform the various process steps of the disclosure. When the communications link comprises a network, the network can comprise any combination of one or more types of networks (e.g., the Internet, a wide area network, a local area network, a virtual private network, etc.). Network adapters may also be coupled to the system to enable the data processing system to become coupled to other data processing systems or remote printers or storage devices through intervening private or public networks. Modems, cable modem and Ethernet cards are just a few of the currently available types of network adapters. Regardless, communications between the computing devices may utilize any combination of various types of transmission techniques.

As discussed herein, various systems and components are described as “obtaining” data. It is understood that the corresponding data can be obtained using any solution. For example, the corresponding system/component can generate and/or be used to generate the data, retrieve the data from one or more data stores (e.g., a database), receive the data from another system/component, and/or the like. When the data is not generated by the particular system/component, it is understood that another system/component can be implemented apart from the system/component shown, which generates the data and provides it to the system/component and/or stores the data for access by the system/component.

While shown and described herein as a method and system for optimizing the placement of SRAFs on a mask, it is understood that the disclosure further provides various alternative embodiments. That is, the disclosure can take the form of an entirely hardware embodiment, an entirely software embodiment or an embodiment containing both hardware and software elements. In a preferred embodiment, the disclosure is implemented in software, which includes but is not limited to firmware, resident software, microcode, etc. In one embodiment, the disclosure can take the form of a computer program product accessible from a computer-usable or computer-readable medium providing program code for use by or in connection with a computer or any instruction execution system, which when executed, enables a computer infrastructure to optimize the placement of SRAFs on a mask. For the purposes of this description, a computer-usable or computer readable medium can be any apparatus that can contain, store, communicate, propagate, or transport the program for use by or in connection with the instruction execution system, apparatus, or device. The medium can be an electronic, magnetic, optical, electromagnetic, infrared, or semiconductor system (or apparatus or device) or a propagation medium. Examples of a computer-readable medium include a semiconductor or solid state memory, such as memory 422, magnetic tape, a removable computer diskette, a random access memory (RAM), a read-only memory (ROM), a tape, a rigid magnetic disk and an optical disk. Current examples of optical disks include compact disk-read only memory (CD-ROM), compact disk-read/write (CD-R/W) and DVD.

A data processing system suitable for storing and/or executing program code will include at least one processing unit 414 coupled directly or indirectly to memory elements through a system bus 418. The memory elements can include local memory, e.g., memory 412, employed during actual execution of the program code, bulk storage (e.g., memory system 422), and cache memories which provide temporary storage of at least some program code in order to reduce the number of times code must be retrieved from bulk storage during execution.

In another embodiment, the disclosure provides a method of generating a system for optimizing the placement of SRAFs on a mask. In this case, a computer infrastructure, such as computer infrastructure 402 (FIG. 8), can be obtained (e.g., created, maintained, having made available to, etc.) and one or more systems for performing the process described herein can be obtained (e.g., created, purchased, used, modified, etc.) and deployed to the computer infrastructure. To this extent, the deployment of each system can comprise one or more of: (1) installing program code on a computing device, such as computing device 404 (FIG. 8), from a computer-readable medium; (2) adding one or more computing devices to the computer infrastructure; and (3) incorporating and/or modifying one or more existing systems of the computer infrastructure, to enable the computer infrastructure to perform the process steps of the disclosure.

As used herein, it is understood that the terms “program code” and “computer program code” are synonymous and mean any expression, in any language, code or notation, of a set of instructions that cause a computing device having an information processing capability to perform a particular function either directly or after any combination of the following: (a) conversion to another language, code or notation; (b) reproduction in a different material form; and/or (c) decompression. To this extent, program code can be embodied as one or more types of program products, such as an application/software program, component software/a library of functions, an operating system, a basic I/O system/driver for a particular computing and/or I/O device, and the like.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims. The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

What is claimed is:

1. A method to reduce the number of necessary SRAF features on a mask, the method comprising:
providing a mask, the mask including a mask shape; and
placing at least two elongated SRAF shapes on the mask such that each elongated SRAF shape extends past at least one edge of the mask shape in at least one direction.

2. The method of claim 1, wherein two elongated SRAF shapes are placed on the mask such that each elongated SRAF shape is substantially parallel to a different edge of the mask shape.

3. The method of claim 1, wherein the mask shape is for a contact.

4. The method of claim 3, wherein the placement of the elongated SRAF shapes is determined by whether the contact is hitting a line of an underlying substrate.

5. The method of claim 4, wherein the elongated SRAF shapes are placed such that the elongated SRAF shapes do not overlap the line of an underlying substrate.

6. The method of claim 1, wherein a ratio of a length of a longer side of the elongated SRAF shapes to a mask shape edge length is greater than or equal to approximately 1.2.

7. The method of claim 1, wherein two elongated SRAF shapes are placed on the mask, and the two elongated SRAF shapes are placed on different sides of the mask shape such that the two elongated SRAF shapes are substantially parallel to each other.

8. The method of claim 1, wherein two elongated SRAF shapes are placed on the mask and the two elongated SRAF shapes are placed on different sides of the mask shape such that the two elongated SRAF shapes are substantially perpendicular to each other.

9. The method of claim 1, wherein each elongated SRAF shape extends past two edges of the mask shape.

10. A mask with an improved SRAF layout, the mask comprising:
a mask shape; and
at least two elongated SRAF shapes, such that each of the elongated SRAF shapes extend past at least one edge of the mask shape.

11. The mask of claim 10, wherein the mask shape is for a contact.

12. The mask of claim 11, wherein the placement of the elongated SRAF shapes is determined by whether the contact is hitting a line of an underlying substrate.

13. The mask of claim 12, wherein the elongated SRAF shapes are placed such that the elongated SRAF shapes do not overlap the line of an underlying substrate.

14. The mask of claim 10, wherein a ratio of a length of a longer side of the elongated SRAF shapes to a target edge length is greater than or equal to approximately 1.2.

15. The mask of claim 10, wherein the mask includes two elongated SRAF shapes, and the two elongated SRAF shapes are placed on different sides of the mask shape such that the two elongated SRAF shapes are substantially parallel to each other.

16. The mask of claim 10, wherein the mask includes two elongated SRAF shapes, and the two elongated SRAF shapes are placed on different sides of the mask shape such that the two elongated SRAF shapes are substantially perpendicular to each other.

17. The mask of claim 10, wherein each elongated SRAF shape extends past two edges of the mask shape.

18. A machine-readable medium having stored thereupon a set of instructions that, when executed by a machine, result in:
providing a mask, the mask including a mask shape; and
placing at least two elongated SRAF shapes on the mask such that each elongated SRAF shape extends past at least one edge of the mask shape in at least one direction.

19. The machine-readable medium of claim 18, wherein said instructions result in:
placing two elongated SRAF shapes on the mask such that each elongated SRAF shape is substantially parallel to a different edge of the mask shape.

20. The machine-readable medium of claim 18, wherein the mask shape is for a contact.
